(19) United States
(12) Patent Application Publication
(10) Pub. No.: US 2014/0237308 A1
(43) Pub. Date: Aug. 21, 2014

(54) TEST CONTROL USING EXISTING IC CHIP PINS

(71) Applicant: Fairchild Semiconductor Corporation, San Jose, CA (US)

(72) Inventor: Juha-Matti Kujala, Kokkola (FI)

(73) Assignee: Fairchild Semiconductor Corporation, San Jose, CA (US)

(21) Appl. No.: 14/185,829

(22) Filed: Feb. 20, 2014

Related U.S. Application Data
(60) Provisional application No. 61/766,822, filed on Feb. 20, 2013.

(51) Int. Cl. G01R 31/3177

(52) U.S. Cl. CPC G01R 31/3177
USPC 714/726

(57) ABSTRACT

An apparatus and method are provided for testing normal circuitry in an integrated circuit, the method including writing test protocols into a plurality of test registers using an enable pin and a switch pin in a first mode, storing a logic high signal in one of the plurality of test registers once the writing is completed, switching from the first mode to a second mode if the one of the plurality of test registers stores the logic high signal, and testing the normal circuitry using the enable pin and the switch pin in the second mode.

This application may form the basis of a benefit and/or priority claim under 35 USC §119 for one or more domestic and/or foreign patent applications.

### FIELD

The present disclosure relates to Integrated Circuit (IC) package testing protocols and controls using existing IC chip pins.

### BACKGROUND

Testing of various components and functions of an integrated circuit (IC) is an essential feature of most ICs. Typically, test circuitry is included on a die and dedicated test pins are provided to enable test equipment to interface to the IC and perform a variety of test procedures. As chip sizes decrease, the real estate available for test pins is ever-decreasing. Thus, there is a need to develop systems and procedures to perform testing of ICs without the need for dedicated test pins.

### BRIEF DESCRIPTION OF DRAWINGS

Features and advantages of the claimed subject matter will be apparent from the following detailed description of example embodiments consistent therewith, where the description should be considered with reference to the accompanying drawings, wherein:

FIG. 1 illustrates an integrated circuit (IC) consistent with various example embodiments of the present disclosure;

FIG. 2 illustrates in more detail some test mode circuitry associated with an IC; and

FIG. 3 illustrates an example of a flowchart of operations according to some example embodiments of the present disclosure.

Although the following Detailed Description will proceed with reference being made to illustrative example embodiments, many alternatives, modifications, and variations thereof will be apparent to those skilled in the art.

### DETAILED DESCRIPTION

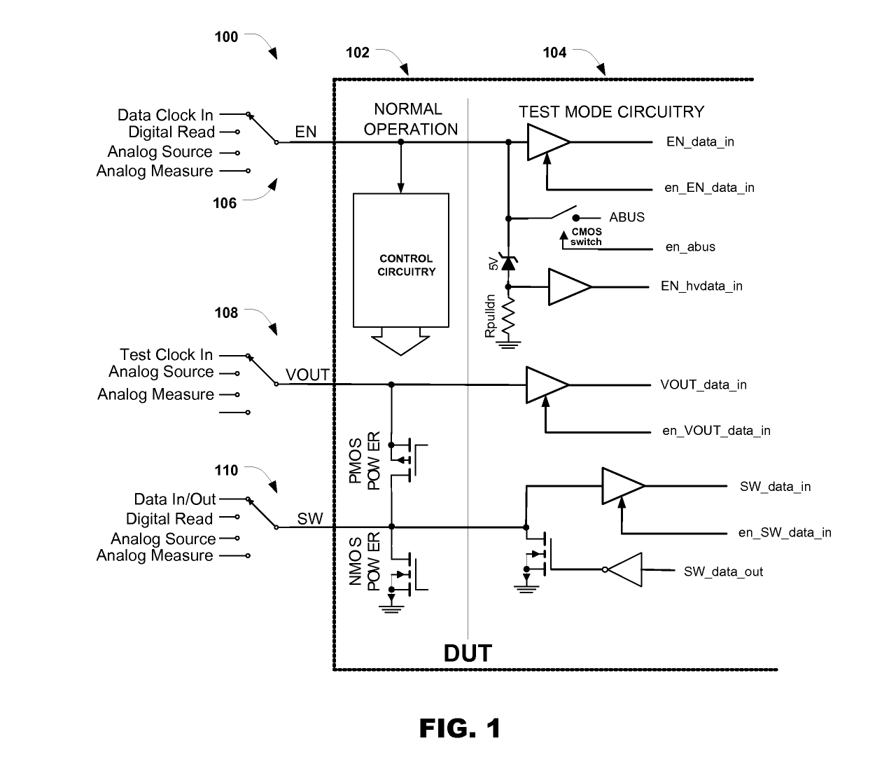

FIG. 1 illustrates an integrated circuit (IC) 100 consistent with various example embodiments of the present disclosure. The IC 100 generally includes functional components 102 of the IC that are used during normal operation and test mode I/O circuitry 104 that is used to test the functional components 102. In this example, the components 102 include various circuitry of a DC/DC converter system (e.g., Boost converter). The test mode I/O circuitry 104 is coupled to typical input/output (IO) pins 106, 108 and 110 that are used by the functional components 102 during normal operation. The typical IO pins used in this example are the enable (EN) pin 106, the voltage output pin (VOUT) 108 and the switch (SW) pin 110. These pins are typically provided with DC/DC converter ICs for the normal operation of the chip, and thus, no dedicated test pins are needed according to the teachings presented herein. For the purposes of this disclosure, normal operation may include conventional functionality of the IC 100.

While FIG. 1 illustrates the EN pin 106, the VOUT pin 108 and the SW pin 110, these are just examples of typical IO pins and example embodiments may vary. For example, any IO pin typically used by the IC 100 may be used to test the functional components 102.

Pins 106, 108 and 110 may be coupled to a test apparatus (not shown) and may be used for analog and digital input and output for various test procedures. For example, the EN pin 106 may be utilized as a data clock input, a digital output, an analog source and/or an analog measurement output. The VOUT pin 108 may be utilized as a test clock input, an analog source input and/or an analog measurement output. The SW pin 110 may be utilized as a data IO, digital read output, analog source input and/or an analog measurement output. Thus, any of the IO pins in the IC 100 may be used for a data clock input, test clock input, a digital output, an analog source, analog measurement output, data IO and/or digital read output. Moreover, these IO pins may be used as a combination of the above during a single test, allowing the testing to include analog signal measurements, digital signal detections, analog and digital signal testing at the same time and/or data interface to the internal test register bits to provide access to the internal test multiplexers and other controls. In addition, some tests may require all of the interfaces above within a sequence of a single test. Of course, these are only examples of the types of analog/digital inputs and outputs that may be used in connection with testing of various functional components of the DC/DC converter system, and in other example embodiments, these pins may be utilized to support other inputs and/or output to support other test procedures. In addition, while this example is directed specifically to a DC/DC converter, the present disclosure has broad applicability to any type of IC where it is desirable to eliminate dedicated test pins and use existing pins for testing of the IC. As illustrated in FIG. 1, the enable pin 106 may be coupled to both a first enable input (EN_data_in) and a second enable input (EN_hvdata_in). For normal operation and typical testing operation, a logic low or logic high signal on the enable pin may result in a logic low or logic high signal on the first enable input and an analog signal may be coupled directly to the first enable input. However, under certain situations, for example when the enable pin is tied to a voltage higher than a threshold voltage, a logic high signal will be seen at the second enable input. Thus, test apparatus (not shown) may use the enable pin 106 to couple to two separate elements within the test mode circuitry 104, coupling a first element using analog or digital signals within a first voltage range and coupling a second element by pulling the voltage at the enable pin higher than the threshold voltage. As an example, the threshold voltage may be an input voltage Vin or a supply voltage Vsupply.

To allow the enable pin 106 to couple to two separate elements within the test mode circuitry 104, FIG. 1 illustrates a zener diode coupled between the second enable input and the enable pin 106 and a pull down resistor Rpulldn coupled between the zener diode and a low reference potential (e.g. ground). If a voltage of the enable pin 106 is greater than the threshold voltage, the zener diode is in breakdown and the second enable input signal goes to a logic High (1).

FIG. 1 also illustrates the switch pin 110 coupled to a switch input (SW_data_in) and a switch coupled between the switch input and a low reference potential (e.g. ground). The switch may be controlled by an inverted switch output (SW_data_out). Based on the switch output (SW_data_out), the switch couples the switch pin 110 and the switch input (SW_data_in) to the low reference potential (e.g. ground).

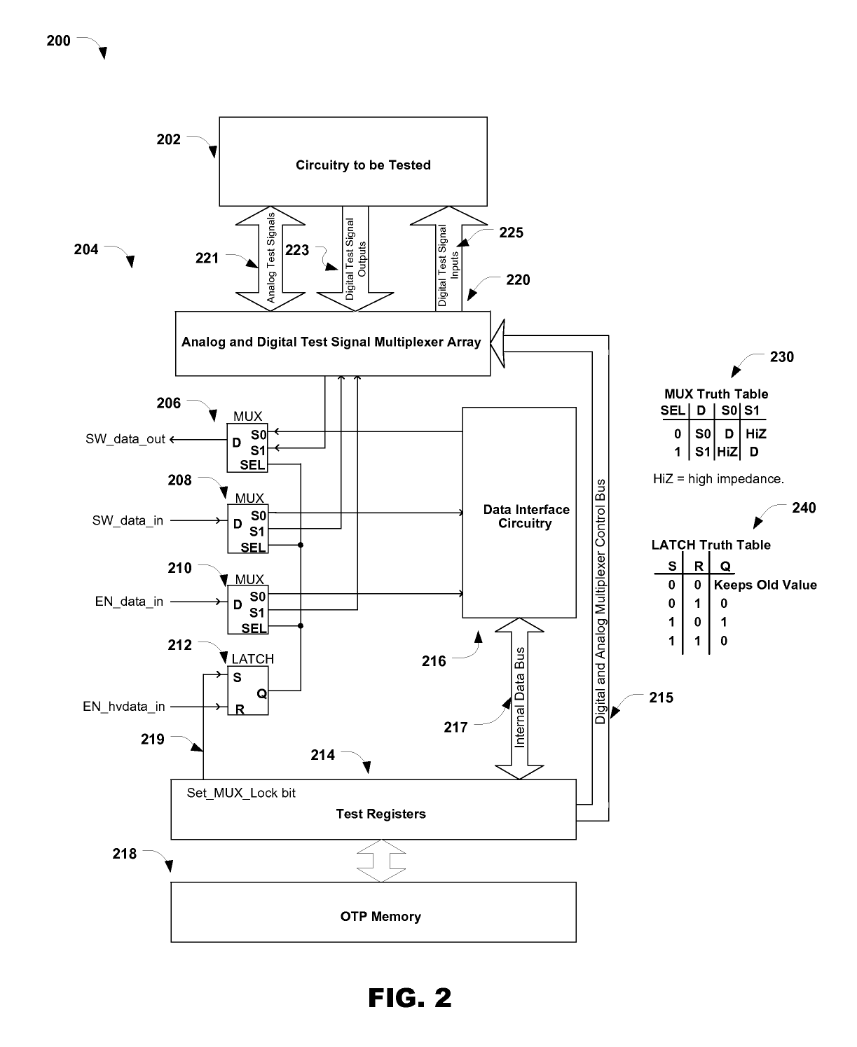

The test mode I/O circuitry 104 is configured to generate a plurality of signals that enable testing of various functional components of the IC 102. FIG. 2 illustrates in more detail test mode circuitry associated with an IC 200. In this example embodiment, the IC 200 includes functional components 202 (“circuitry to be tested”) and test mode circuitry 204. The test mode circuitry includes a plurality of multiplexer circuits 206, 208 and 210 and a latch circuit 212. In this example, multiplexer 206 is configured to receive an output signal (SW_data_out), which is output to test apparatus (not shown) via the SW pin 110 (FIG. 1). Multiplexer 208 is configured to receive an input signal (SW_data_in), which is input from test apparatus (not shown) via the SW pin 110 (FIG. 1). Multiplexer 210 is configured to receive an input signal (EN_data_in), which is input from test apparatus (not shown) via the EN pin 106 (FIG. 1). Latch circuitry 212 is configured to receive an input signal (EN_hvdata_in), which is input from test apparatus (not shown) via the EN pin 106 (FIG. 1).

The test mode circuitry 204 also includes test registers 214 that are used for various tests of the functional components 202. Analog and digital test signal multiplexer array 220 is coupled to the test registers (via bus 215) and configured to interface with the functional components 202 via analog and digital buses 221, 223 and 225. Data interface circuitry 216 is configured to interface the multiplexers 206, 208 and 210 with the test registers 214 via bus 217. Memory 218 may include, for example, ROM memory to set values after test procedures have concluded. The test registers 214 are configured to generate a lock bit 219 for the latch circuitry 212. The lock bit 219 changes the selection of the multiplexers 206, 208 and 210 between S0 and S1 to enable the multiplexers for testing and to disable the multiplexers after testing. For example, when the testing protocols are written into the test registers 214, the lock bit 219 is asserted to a logic High (1). Upon testing being completed, the lock bit 219 may be asserted to a logic Low (0) for normal operation.

In operation, and with continued reference to FIGS. 1 and 2, a test mode is activated when a test mode entry sequence is entered on the EN pin 106. A test sequence may be written into the test registers 214, via the data interface circuitry 216, from multiplexers 208 and 210 using the SW_data_in signal on the SW pin 110 and the EN_data_in signal on the EN pin 106. During this time, the Q output of the latch circuitry 212 is set to a logic Low (0), which causes the multiplexers 206, 208 and 210 to select the S0 output to communicate with the data interface circuitry 216 and enable writing to the test registers 214 to write the test protocols to perform a test of the functional components 202 (see MUX truth table 230). Once test protocols are written into the test registers 214, the test registers 214 are configured to assert the lock bit 219, and the latch circuitry 212 changes the output Q signal to a logic High (1) (see Latch truth table 240). When the Q output of the latch circuitry changes to a logic High (1), MUXs 206, 208 and 210 are coupled to the multiplexer array 220, via S1, and decoupled from the data interface circuitry 216. A test may be performed using the protocols in the test registers 214 and analog and/or digital IO using multiplexers 206, 208 and/or 210. Once the test procedure is completed, the EN_hvdata_data input signal on the EN pin 106 may be pulled greater than the input voltage Vin (not shown) so that the zener diode (FIG. 1) is in breakdown and the EN_hvdata_in signal goes to a logic High (1). The Q output of the latch circuitry 212 changes state and decouples the MUXs 206, 208 and 210 from the multiplexer array 220 and couples the MUXs 206, 208 and 210 to the data interface circuitry to enable writing to the test registers 214 for additional test procedures. Upon testing being completed, the lock bit 219 may be asserted to a logic Low (0) for normal operation.

FIG. 3 illustrates an example of a flowchart of operations according to some example embodiments of the present disclosure. In operation 310, test protocols may be written into a plurality of test registers using an enable pin and a switch pin in a first mode. In operation 320, a logic high signal may be stored in one of the plurality of test registers once the writing is completed. In operation 330, the IC 200 may switch from the first mode to a second mode if the one of the plurality of test registers stores the logic high signal. In operation 340, the normal circuitry may be tested using the enable pin and the switch pin in the second mode. In operation 350, the enable pin may be pulled to a voltage higher than an input voltage once the testing is complete. In operation 360, additional test protocols may be written into the plurality of test registers while the one of the plurality of test registers stores the logic high signal and the enable pin is pulled higher than the input voltage. In operation 370, the normal circuitry may be tested with the additional test protocols using the enable pin and the switch pin if the voltage of the enable pin is no longer held higher than the input voltage and the one of the plurality of test registers stores the logic high signal. Finally, in operation 380, a logic low signal may be stored in the one of the plurality of test registers to return to normal operation if there are no additional test protocols to test on the normal circuitry

As used herein, the term “multiplexer” includes any device configured to select one input from several inputs to send to the output. Multiplexors 206, 208 and 210 are used to allow both the analog and digital test signal multiplexer array 220 and the data interface circuitry 216 to couple to the input/output pins. While FIG. 2 illustrates the use of multiplexers 206, 208 and 210, example embodiments are not limited thereto and may vary. For example, the multiplexers may be replaced with switch circuitry configured to couple either S0 or S1 to the respective pins based on the latch circuitry 212.

The term “test registers,” as used in any example embodiment herein, may include, for example, any storage that can be accessed quickly and is not part of a main memory of the IC 200. However, example embodiments are not limited thereto and may vary. For example, some example embodiments may include the test registers in the main memory of the IC 200 for simplicity.

The term “logic signal low,” as used in any example embodiment herein, may imply, for example, a voltage near a low reference potential (e.g. ground) and may represent a digital “0.” Similarly, the term “logic signal high” may imply a voltage near a high reference potential (e.g. voltage supply) or an input voltage Vin and represents a digital “1.” In certain situations, such as for the enable pin, there may be two values for a “logic signal high.” For example, a voltage near a low reference potential (approximately 0V) on the enable pin may be seen as a “logic signal low” by both the first enable input and the second enable input. However, a voltage near an input voltage Vin (e.g. 3V) may be seen as a “logic signal high” to the first enable input but as a “logic signal low” to the second enable input due to the presence of the zener diode and the pulldown resistor. Therefore, a voltage above the input voltage (such as a voltage greater than 5V) may be seen as a “logic signal high” to both the first enable input and the second enable input, as it places the zener diode in breakdown.

All descriptions of “logic signal high” and “logic signal low” or other data states with respect to various example embodiments of the disclosure are only provided as an example. Example embodiments are not limited thereto and may vary. For example, one of ordinary skill in the art would understand that the signals could be inverted without any change in functionality.

The term “latch circuitry,” as used in any example embodiment herein, may include, for example, any flip-flop or latch that has two stable states and that is used to store state information. While the latch circuitry 212 is controlled by both the second enable input (EN_hvdata_in) and the lock bit 219, example embodiments are not limited thereto and may vary. For example, the latch circuitry 212 may be controlled by only one of the second enable input and the lock bit 219, or by either. For example, the latch circuitry 212 may toggle whenever either the second enable input or the lock bit 219 is a logic high signal.

The term “circuitry” or “circuit”, as used in any example embodiment herein, may comprise, for example, singly or in any combination, hardwired circuitry, programmable circuitry, state machine circuitry, and/or circuitry available in a larger system, for example, discrete elements that may be included as part of an integrated circuit. In addition, any of the switch devices described herein may include any type of known or after-developed switch circuitry such as, for example, MOS transistor, BJT, etc.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and some example embodiments have been described herein. The features, aspects, and example embodiments are susceptible to combination with one another as well as to variation and modification, as will be understood by those having skill in the art. The present disclosure should, therefore, be considered to encompass such combinations, variations, and modifications.

What is claimed is:

1. An integrated circuit comprising:
functional circuitry to be tested;
data interface circuitry;
an analog and digital test signal multiplexer array;
a plurality of test registers;
a first multiplexer configured to output to a switch pin and to select an input from the data interface circuitry in a first mode and from the analog and digital test signal multiplexer array in a second mode;
a second multiplexer configured to receive an input from the switch pin and to output to the data interface circuitry in the first mode and to the analog and digital test signal multiplexer array in the second mode;
a third multiplexer configured to receive an input from an enable pin and to output to the data interface circuitry in the first mode and to the analog and digital test signal multiplexer array in the second mode;
latch circuitry coupled to the first multiplexer, the second multiplexer and the third multiplexer and configured to select the first mode or the second mode based on an input from the enable pin and an input from one of the plurality of test registers.

2. The integrated circuit of claim 1, wherein the enable pin and the switch pin are used for data interface in the first mode and as analog/digital test pins in the second mode.

3. The integrated circuit of claim 1, wherein the latch circuitry receives a logic high signal from the enable pin if the enable pin is pulled to a voltage higher than an input voltage of the integrated circuit.

4. The integrated circuit of claim 1, wherein the latch circuitry is configured to select the second mode if a voltage of the enable pin is not greater than an input voltage and the input from one of the plurality of test registers is a logic high signal.

5. The integrated circuit of claim 4, wherein the latch circuitry is configured to switch from the second mode to the first mode if the voltage of the enable pin is greater than the input voltage.

6. The integrated circuit of claim 1, further comprising:
a zener diode coupled between the latch circuitry and the enable pin, the zener diode configured to output a logic high signal if the enable pin is pulled greater than an input voltage.

7. The integrated circuit of claim 1, further comprising:
a voltage out pin configured to output a voltage in the first mode and to receive a test clock input in the second mode.

8. The integrated circuit of claim 1, wherein
the plurality of test registers are configured to receive test protocols in the first mode, and
the functional circuitry is tested using the test protocols in the second mode.

9. The integrated circuit of claim 8, wherein the one of the plurality of test registers is set to a logic high signal once the test protocols are written in the plurality of test registers.

10. The integrated circuit of claim 9, wherein the latch circuitry is configured to select the second mode if the one of the plurality of test registers is set to the logic high signal and a voltage of the enable pin is not greater than an input voltage.

11. A method for testing normal circuitry in an integrated circuit, the method comprising:
writing test protocols into a plurality of test registers using an enable pin and a switch pin in a first mode;
storing a logic high signal in one of the plurality of test registers once the writing is completed;
switching from the first mode to a second mode if the one of the plurality of test registers stores the logic high signal; and
testing the normal circuitry using the enable pin and the switch pin in the second mode.

12. The method of claim 11, further comprising:
pulling the enable pin to a voltage higher than an input voltage once the testing is complete; and
writing additional test protocols into the plurality of test registers while the one of the plurality of test registers stores the logic high signal and the enable pin is pulled higher than the input voltage;
testing the normal circuitry with the additional test protocols using the enable pin and the switch pin if the voltage of the enable pin is no longer held higher than the input voltage and the one of the plurality of test registers stores the logic high signal.

13. The method of claim 12, further comprising:
storing a logic low signal in the one of the plurality of test registers to return to normal operation if there are no additional test protocols to test on the normal circuitry.

14. The method of claim 11, further comprising:
outputting an output voltage from a voltage output pin in the first mode; and
inputting a test clock to the voltage output pin in the second mode.

15. The method of claim 11,
coupling the enable pin and the switch pin to data interface circuitry in the first mode; and
coupling the enable pin and the switch pin to an analog and digital test signal multiplexer array in the second mode.

16. An integrated circuit comprising:
one or more operational pins configured to input/output data to functional circuitry during conventional functionality of the integrated circuit;
latch circuitry configured to select a first mode or a second mode for the integrated circuit based on an input from an enable pin of the one or more operational pins and an input from one of a plurality of test registers; and
one or more multiplexers coupled to the one or more operational pins and configured to couple the one or more operational pins to data interface circuitry in the first mode and an analog and digital test signal multiplexer array in the second mode.

17. The integrated circuit of claim 16, wherein the one or more multiplexers further comprise:
a first multiplexer configured to output to a switch pin of the one or more operational pins and to select an input from the data interface circuitry in the first mode and from the analog and digital test signal multiplexer array in the second mode;
a second multiplexer configured to receive an input from the switch pin and to output to the data interface circuitry in the first mode and to the analog and digital test signal multiplexer array in the second mode;
a third multiplexer configured to receive an input from the enable pin and to output to the data interface circuitry in the first mode and to the analog and digital test signal multiplexer array in the second mode;

18. The integrated circuit of claim 16, wherein the latch circuitry receives a logic high signal from the enable pin if the enable pin is pulled to a voltage higher than an input voltage of the integrated circuit.

19. The integrated circuit of claim 16, further comprising:
a zener diode coupled between the latch circuitry and the enable pin, the zener diode configured to output a logic high signal to the latch circuitry if the enable pin is pulled greater than an input voltage.

20. The integrated circuit of claim 16, wherein
the plurality of test registers are configured to receive test protocols in the first mode, and
the functional circuitry is tested using the test protocols in the second mode.
